(19) United States
(12) Patent Application Publication
(10) Pub. No.: US 2026/0068594 A1
(43) Pub. Date: Mar. 5, 2026

(54) CARRIER ASSEMBLY FOR SEMICONDUCTOR DEVICE

(71) Applicant: SAMSUNG ELECTRONICS CO., LTD., Suwon-si (KR)

(72) Inventors: Sunghyeon PARK, Suwon-si (KR); Youngse KIM, Suwon-si (KR); Youngseok JUNG, Suwon-si (KR); Wontak HAN, Suwon-si (KR)

(73) Assignee: SAMSUNG ELECTRONICS CO., LTD., Suwon-si (KR)

(21) Appl. No.: 19/309,039

(22) Filed: Aug. 25, 2025

(30) Foreign Application Priority Data
Aug. 27, 2024 (KR) 10-2024-0114793

(51) Int. Cl. H01L 21/683; H01L 23/00; H01L 25/065; H10B 80/00

(52) U.S. Cl. CPC H01L 21/6836; H10B 80/00

(57) ABSTRACT

A carrier assembly for semiconductor device may include a first carrier attached to a front surface of a base wafer, the first carrier including a first stiffness reinforcement structure having a first surface facing the base wafer and a second surface opposite to the first surface and including a first adhesive member disposed between the first surface of the first reinforcement structure and the front surface of the base wafer; and a second carrier attached to the second surface of the first stiffness reinforcement structure, the second carrier including a second stiffness reinforcement structure having a first surface facing the base wafer and a second surface opposite to the first surface of the second stiffness reinforcement structure and including a second adhesive member disposed between the first stiffness reinforcement structure and the second stiffness reinforcement structure.

### CROSS-REFERENCE TO RELATED APPLICATION

This application claims priority under 35 U.S.C. § 119 to Korean Patent Application No. 10-2024-0114793, filed on Aug. 27, 2024, in the Korean Intellectual Property Office (KIPO), the contents of which are herein incorporated by reference in their entirety.

### BACKGROUND

### 1. Field

Example embodiments relate to a carrier assembly for semiconductor device. More particularly, example embodiments relate to a carrier assembly for semiconductor device configured to reduce warpage of a wafer during a manufacturing process of a semiconductor package.

### 2. Description of the Related Art

As semiconductor chips become more advanced, a thickness of a device layer having circuits and other components formed therein may increase, but a proportion of silicon (Si) may be gradually decreasing. Due to these, a difference in coefficient of thermal expansion may increase, and warpage may increase. In particular, in a chip-on-wafer (COW) process, as the number of core chips stacked on a buffer chip increases, warpage may increase. Therefore, a phenomenon in which a wafer lifts vertically (vacuum error) occurs, causing alignment errors, which reduces production efficiency. Additionally, in the process of pressing the wafer to mitigate warpage, cracks in the semiconductor chip may occur.

### SUMMARY

Example embodiments provide a carrier assembly for semiconductor device configured to reduce warpage of a wafer.

According to example embodiments, a carrier assembly for semiconductor device includes a first carrier attached to a front surface of a base wafer, the first carrier including a first stiffness reinforcement structure having a first surface facing the base wafer and a second surface opposite to the first surface and a first adhesive member disposed between the first surface of the first stiffness reinforcement structure and the front surface of the base wafer; and a second carrier attached to the second surface of the first stiffness reinforcement structure, the second carrier including a second stiffness reinforcement structure having a first surface facing the base wafer and a second surface opposite to the first surface of the second stiffness reinforcement structure and including a second adhesive member disposed between the first stiffness reinforcement structure and the second stiffness reinforcement structure.

According to example embodiments, carrier assembly for semiconductor device includes a plurality of stiffness reinforcement structures each including at least one of silicon (Si) or glass to prevent warpage of a base wafer; a first adhesive member having a first adhesion strength, the first adhesive member disposed between a front surface of the base wafer and an uppermost stiffness reinforcement structure among the plurality of stiffness reinforcement structures such that the uppermost stiffness reinforcement structure is detachably connected to the base wafer; and at least one second adhesive member having a second adhesion strength greater than the first adhesion strength, the at least one second adhesive member disposed between the plurality of stiffness reinforcement structures to integrally connect the plurality of stiffness reinforcement structures.

According to example embodiments, a carrier assembly for a semiconductor device includes a stiffness reinforcement structure including at least one of silicon (Si) or glass to prevent warpage of the base wafer, the first stiffness reinforcement structure having a first thickness; a first adhesive member having a first adhesion strength, the first adhesive member disposed between the first stiffness reinforcement structure and the base wafer such that the first stiffness reinforcement structure is detachably attached to the base wafer; a second stiffness reinforcement structure spaced apart in a vertical direction from the first stiffness reinforcement structure, the second stiffness reinforcement structure including at least one of silicon (Si) or glass to prevent warpage of the base wafer, the second stiffness reinforcement structure having a second thickness; and a second adhesive member having a second adhesion strength greater than the first adhesion strength, the second adhesive member disposed between the first stiffness reinforcement structure and the second stiffness reinforcement structure such that the first and second stiffness reinforcement structures are integrally connected, wherein a sum of the first thickness and the second thickness is within a range from 780 μm to 1550 μm.

According to example embodiments, in a method for manufacturing a semiconductor package, a first carrier including a first stiffness reinforcement structure and a first adhesive member may be provided, the first adhesive member provided on the first stiffness reinforcement structure. The first carrier may be detachably attached to a front surface of a base wafer via the first adhesive member. A plurality of upper pads may be formed on a backside surface of the base wafer. A lamination tape may be attached to the backside surface of the base wafer to cover the plurality of upper pads. A second carrier may be provided, the second carrier including a second stiffness reinforcement structure and a second adhesive member provided on the second stiffness reinforcement structure. The first carrier may be integrally attached to the second carrier via the second adhesive member to form a semiconductor device carrier assembly including the first and second carriers.

According to example embodiments, a carrier assembly for semiconductor device may include a first carrier attached to a base wafer and a second carrier attached to the first carrier. The first carrier may include a first stiffness reinforcement structure and a first adhesive member configured to attach the first stiffness reinforcement structure to the base wafer. The second carrier may include a second stiffness reinforcement structure and a second adhesive member configured to attach the second stiffness reinforcement structure to the first stiffness reinforcement structure.

The first and second stiffness reinforcement structure may include at least one of silicon (Si) or glass to prevent warpage of the base wafer.

Accordingly, the carrier assembly for semiconductor device can reduce warpage of wafer generated during the semiconductor manufacturing process. Furthermore, alignment errors and cracks caused by the warpage can be prevented.

### BRIEF DESCRIPTION OF THE DRAWINGS

FIG. 1 is a perspective view illustrating a carrier assembly for semiconductor device according to example embodiments.

FIG. 2 is a cross-sectional view taken along the line A-A′ in FIG. 1.

FIG. 3 is an enlarged cross-sectional view illustrating portion ‘M1’ in FIG. 2.

FIG. 4 is a graph illustrating a relationship between thickness and warpage of the carrier assembly for semiconductor device according to example embodiments.

FIGS. 5 to 22 are views illustrating a method for manufacturing a semiconductor package according to example embodiments.

FIG. 23 is a perspective view illustrating a carrier assembly for semiconductor device according to example embodiments.

FIG. 24 is an enlarged cross-sectional view illustrating the carrier assembly for semiconductor device of FIG. 23.

FIG. 25 is a perspective view illustrating a carrier assembly for semiconductor device according to example embodiments.

### DETAILED DESCRIPTION OF EXAMPLE EMBODIMENTS

Hereinafter, example embodiments will be explained in detail with reference to the accompanying drawings.

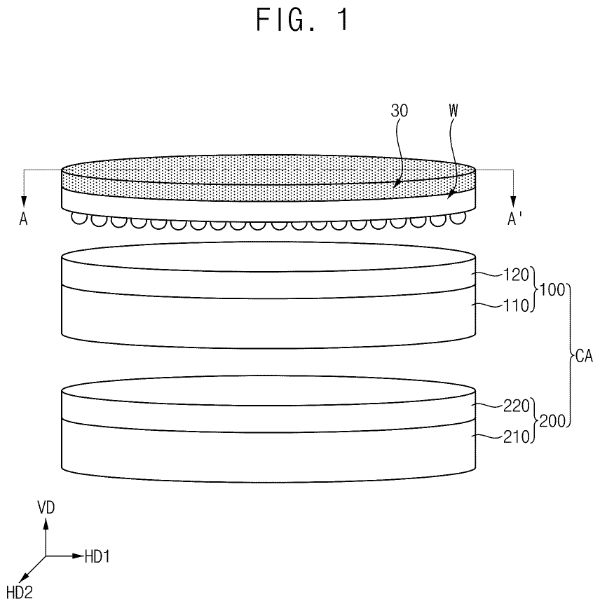

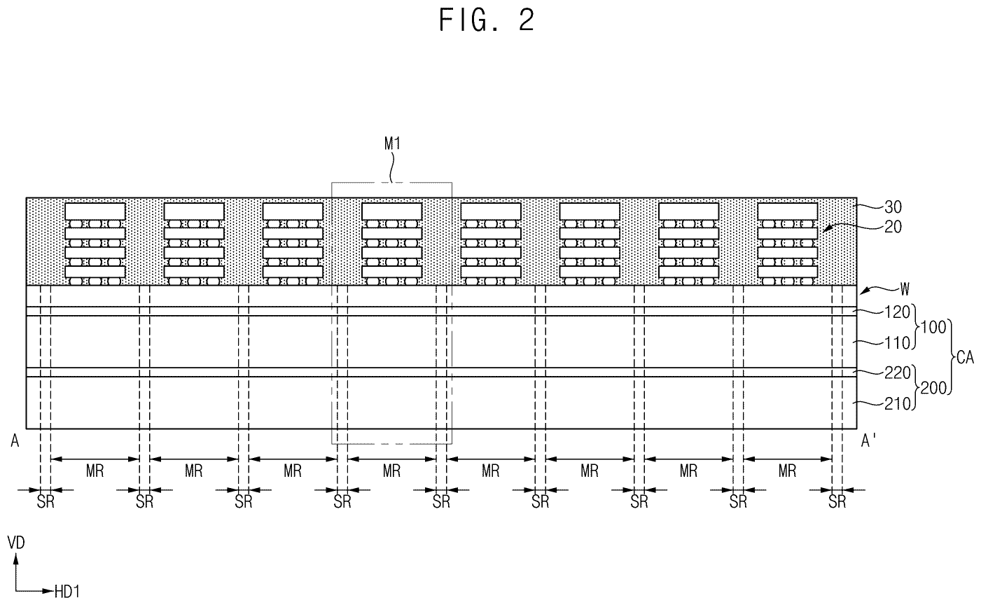

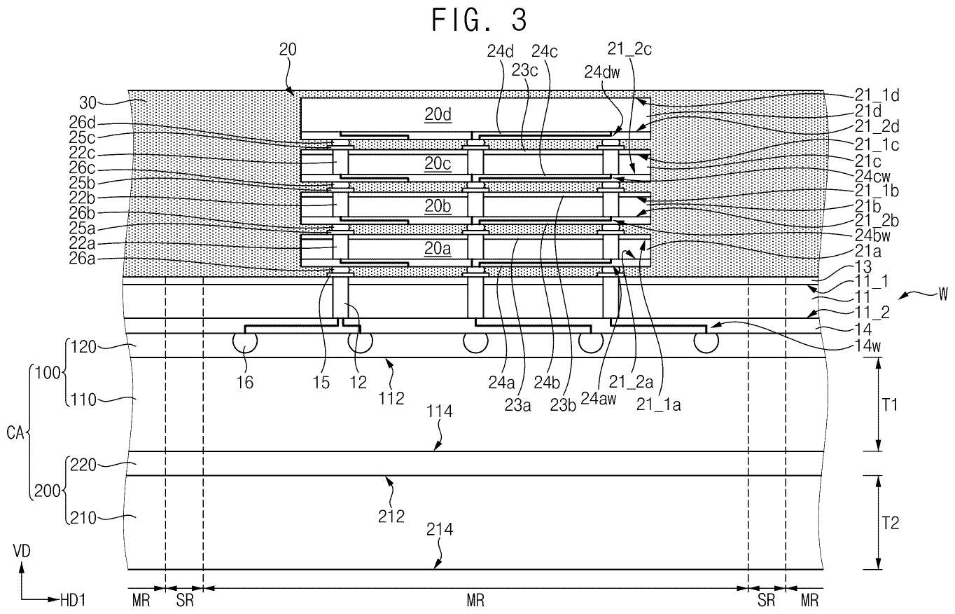

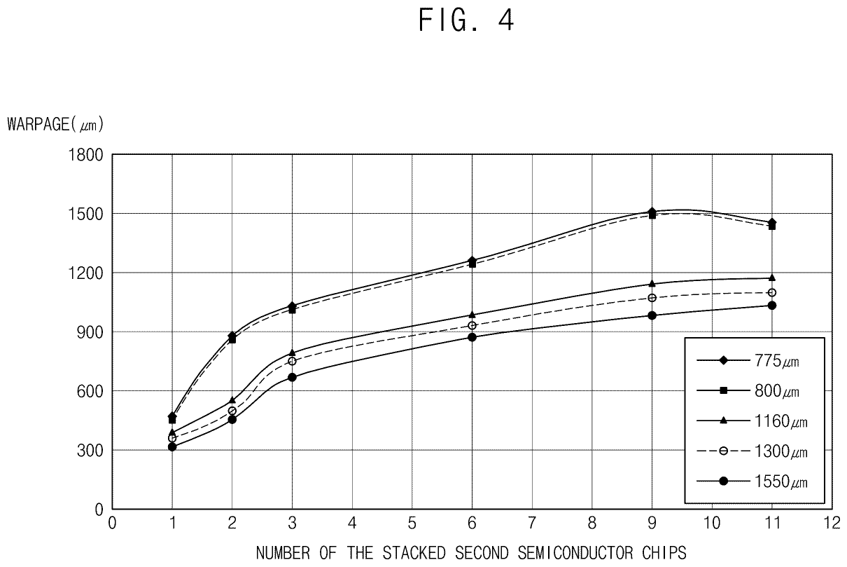

FIG. 1 is a perspective view illustrating a carrier assembly for semiconductor device according to example embodiments. FIG. 2 is a cross-sectional view taken along the line A-A′ in FIG. 1. FIG. 3 is an enlarged cross-sectional view illustrating portion ‘M1’ in FIG. 2. FIG. 4 is a graph illustrating a relationship between thickness and warpage of the carrier assembly for semiconductor device according to example embodiments.

Referring to FIGS. 1 to 3, a carrier assembly for semiconductor device CA may include a first carrier 100 and a second carrier 200 that are sequentially disposed in a vertical direction VD on a base wafer W. The carrier assembly for a semiconductor device may be a structure configured to handle the wafer during the semiconductor package manufacturing process. Additionally, the carrier assembly may be a structure configured to be attached to a surface of a wafer to prevent warpage of the wafer during the semiconductor package manufacturing process.

In example embodiments, the first carrier 100 may include a first stiffness reinforcement structure 110 attached to a front surface of the base wafer W and a first adhesive member 120 disposed between the first stiffness reinforcement structure 110 and the base wafer W. The first carrier 100 may directly contact the base wafer W and be integrally coupled with the base wafer W for handling the base wafer W.

The first stiffness reinforcement structure 110 may include a first surface 112 facing the base wafer W and a second surface 114 opposite to the first surface 112. The first stiffness reinforcement structure 110 may be a structure configured to prevent warpage of the base wafer W during the semiconductor package manufacturing process. For example, the first stiffness reinforcement structure 110 may have a circular shape to allow the base wafer W to be seated, when viewed from a plan view.

The first stiffness reinforcement structure 110 may include at least one of silicon (Si) or glass to prevent warpage of the base wafer W. For example, the first stiffness reinforcement structure 110 may be a silicon wafer used in the semiconductor manufacturing process.

The first adhesive member 120 may a structure configured to bond the first stiffness reinforcement structure 110 and the base wafer W. For example, the first adhesive member may cover the front surface of the base wafer W to integrally bond the first stiffness reinforcement structure 110 with the base wafer W.

The first adhesive member 120 may include a high heat-resistant material to withstand heat generated during a soldering process for electrically connecting at least one semiconductor chip mounted on the backside surface of the base wafer W with the base wafer W. For example, the first adhesive member may include an epoxy material.

In example embodiments, the second carrier 200 may include a second stiffness reinforcement structure 210 attached to the first carrier 100 and a second adhesive member 220 disposed between the first stiffness reinforcement structure 110 and the second stiffness reinforcement structure 210. The second carrier 200 may be integrally coupled with the first carrier 100 to reinforce the stiffness of the first carrier 100.

The second stiffness reinforcement structure 210 may include a first surface 212 facing the first stiffness reinforcement structure 110 and a second surface 214 opposite to the first surface 212. The second stiffness reinforcement structure 210 may be a structure configured to prevent warpage of the base wafer W during the semiconductor package manufacturing process. For example, the second stiffness reinforcement structure 210 may have a circular shape to allow the base wafer W to be seated, when viewed from a plan view.

The second stiffness reinforcement structure 210 may include at least one of silicon (Si) or glass to prevent warpage of the base wafer W. For example, the second stiffness reinforcement structure 210 may be a silicon wafer used in the semiconductor manufacturing process.

The second adhesive member 220 may be a structure configured to bond the first stiffness reinforcement structure 110 and the second stiffness reinforcement structure 210. For example, the second adhesive member may be disposed between the second surface 114 of the first stiffness reinforcement structure 110 and the first surface 212 of the second stiffness reinforcement structure 210, thereby integrally bonding the first and second stiffness reinforcement structures 110 and 210.

The second adhesive member 220 may include a high heat-resistant material to withstand the heat generated during the soldering process for electrically connecting at least one semiconductor chip mounted on the backside surface of the base wafer W with the base wafer W. For example, the second adhesive member may include an epoxy material.

The first stiffness reinforcement structure 110 may have a first thickness T1, and the second stiffness reinforcement structure 210 may have a second thickness T2.

The sum of the first thickness T1 and the second thickness T2 may be greater than 775 μm. For example, in semiconductor manufacturing processes, a silicon wafer may be used for handling the wafer. The thickness of the silicon wafer may be 775 μm. Accordingly, the carrier assembly for semiconductor device CA may have stiffness greater than the silicon wafer, effectively preventing warpage of the base wafer W.

For example, the sum of the first thickness T1 and the second thickness T2 may be within the range from 780 μm to 1550 μm. In case that the sum of the first and second thicknesses T1 and T2 is within this range, the carrier assembly for semiconductor device CA may have relatively strong stiffness, effectively preventing warpage of the base wafer W.

As the sum of the first and second thicknesses T1 and T2 increases, the carrier assembly for semiconductor device CA may have relatively stronger stiffness, thereby more effectively preventing warpage of the base wafer W.

For example, the first and second thicknesses T1 and T2 may be substantially the same as each other. For example, each of the first thickness T1 and the second thickness T2 may be about 775 μm. Accordingly, a standard silicon wafer, which is commonly used in semiconductor manufacturing processes to handle the wafer, can be used, thereby preventing an increase in process costs (for example, there is no need to modify the manufacturing equipment).

As used herein, the expression “substantially the same” between two thicknesses may refer to being at a same thickness relative to the thickness compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

The first adhesive member 120 may have a first adhesion strength, while the second adhesive member 220 may have a second adhesion strength greater than or equal to the first adhesion strength. For example, the first adhesive member may be used to attach the first stiffness reinforcement structure 110 and the base wafer W in a detachable manner, while the second adhesive member may be used to attach the first and second stiffness reinforcement structures 110 and 210 in a detachable or semi-permanent manner.

Although several stiffness reinforcement structures are illustrated in the figures, it will be understood that these are exemplary and the present inventive concept is not limited thereto. Accordingly, the number, size, shape, etc. of the stiffness reinforcement structures may be changed.

Hereinafter, a semiconductor device, which is attached to the carrier assembly CA and handled, will be described.

For example, the semiconductor device may include a base wafer W having a plurality of mounting regions MR and a scribe lane region SR surrounding the mounting regions, and a plurality of semiconductor chips 20 mounted on the plurality of mounting regions MR of the base wafer W. Additionally, the semiconductor device may further include a molding member 30 covering the plurality of semiconductor chips 20. For example, the semiconductor device may be a wafer-level package (WLP). Alternatively, the semiconductor device may be a wafer including a plurality of semiconductor chips.

The base wafer W may be a wafer including a plurality of base chips, which are respectively disposed in the plurality of mounting regions MR. The plurality of base chips may be separated along the scribe lane region SR, so each of the plurality of base chip is individualized. For example, the base chip may be a buffer chip included in a high bandwidth memory (HBM) device. The buffer chip may serve to connect and organize electrical signals between a plurality of memory chips and a controller chip.

The base wafer W may include a base substrate 11 having first and second surfaces 11_1 and 11_2 opposite to each other, a plurality of through vias 12 passing through the base substrate 11, an upper insulation layer 13 disposed on the first surface 11_1 of the base substrate 11 to at least partially expose one end portion of each of the plurality of through vias 12, a plurality of lower redistribution wirings 14w electrically connected to the second end portion of each of the through vias 12 and disposed on the second surface 11_2 of the base substrate 11, a plurality of upper pads 15 respectively disposed on the exposed end portion of the plurality of through vias 12, and a plurality of external connection members 16 electrically connected to the lower redistribution wirings 14w and disposed on the lower redistribution layer 14. For example, the second surface 11_2 of the base substrate 11 may be an active surface where the circuit is formed, while the first surface 11_1 may be a passive backside surface.

The plurality of semiconductor chips 20 may include first to fourth semiconductor chips 20a, 20b, 20c and 20d. For example, the semiconductor chips may be electronic devices in which memory chips such as DRAM are stacked and electrically connected. The first to fourth semiconductor chips may be core chips included in a high bandwidth memory (HBM) device. For instance, the individualized base chip of the base wafer W and the plurality of semiconductor chips 20 mounted on the individualized base chip may collectively be referred to as a high bandwidth memory (HBM) device.

Although several semiconductor chips are illustrated in the drawings, it should be understood that the invention is not limited to this. Therefore, the shape, number, size, and arrangement of the semiconductor chips can be changed.

The first to fourth semiconductor chips 20a, 20b, 20c, and 20d may be sequentially mounted along the vertical direction VD on the mounting region of the base wafer W. For example, the first semiconductor chip 20a as the lowermost chip may be mounted on the upper pads 15 of the base wafer W, and the second to fourth semiconductor chips 20b, 20c, and 20d may be mounted sequentially on the first semiconductor chip 20a.

The first semiconductor chip 20a may include a first substrate 21a having first and second surfaces 21_1a and 21_2a opposite to each other, a plurality of first vias 22a passing through the first substrate 21a between the first and second surfaces of the first substrate, a first insulation layer 23a disposed on the first surface 21_1a of the first substrate 21a to at least partially expose first end portion of each of a plurality of first vias 22a, a plurality of first redistribution wirings 24aw electrically connected to a second end portion of each of the plurality of first vias 22a, and a first redistribution layer 24a disposed on the second surface 21_2a of the first substrate 21a. The first semiconductor chip 20a may further include a plurality of first pads 25a respectively disposed on the exposed end portion of each of the plurality of first vias 22a and a plurality of first conductive connection members 26a disposed on the first redistribution layer 24a to be electrically connected to the first redistribution wirings 24aw. For example, the second surface 21_2a of the first substrate may be the active surface where the circuit is formed, while the first surface 21_1a may be the inactive backside surface.

The second and third semiconductor chips 20b and 20c may have substantially the same configuration as the first semiconductor chip 20a, so their detailed description is omitted here.

The fourth semiconductor chip 20d may include a fourth substrate 21d having first and second surfaces 21_1d and 21_2d opposite to each other, a fourth redistribution layer 24d disposed on the second surface 21_2d of the fourth substrate 21d and including a plurality of fourth redistribution wirings 24dw, and a plurality of fourth conductive connection members 26d disposed on the fourth redistribution layer 24d to be electrically connected to the plurality of fourth redistribution wirings 24dw. For example, the second surface 21_2d of the fourth substrate may be the active surface where the circuit is formed, while the first surface 21_1a may be the inactive backside surface.

The base wafer W may be integrally bonded to the carrier assembly for a semiconductor device CA through the first adhesive member 120 of the carrier assembly CA. For example, the first adhesive member may be disposed on the second surface 11_2 of the base wafer W, which is the front surface, to cover the plurality of external connection members 16 of the base wafer W. Therefore, the first adhesive member can prevent damage to the external connection members 16.

Hereinafter, experimental data about the carrier assembly CA in accordance with example embodiments will be described.

FIG. 4 is a graph illustrating a relationship between thickness and warpage of a carrier assembly for semiconductor device according to example embodiments In FIG. 4, the vertical axis may represent the amount of warpage occurring on the base wafer W, and the horizontal axis represents the number of semiconductor chips 20 mounted on the base wafer W. The graph labeled ‘775 μm’ in FIG. 4 may represent the change in warpage of the base wafer W as the number of semiconductor chips 20 varies in case that the thickness of the carrier assembly CA is 775 μm. The graph labeled ‘800 μm’ in FIG. 4 may represent the change in warpage of the base wafer W as the number of semiconductor chips 20 varies in case that the thickness of the carrier assembly CA is 800 μm. The graph labeled ‘1160 μm’ in FIG. 4 may represent the change in warpage of the base wafer W as the number of semiconductor chips 20 varies in case that the thickness of the carrier assembly CA is 1160 μm. The graph labeled ‘1300 μm’ in FIG. 4 may represent the change in warpage of the base wafer W as the number of semiconductor chips 20 varies in case that the thickness of the carrier assembly CA is 1300 μm. The graph labeled ‘1550 μm’ in FIG. 4 may represent the change in warpage of the base wafer W as the number of semiconductor chips 20 varies in case that the thickness of the carrier assembly CA is 1550 μm. Specifically, the thickness of the carrier assembly for a semiconductor device may be the sum of the first thickness T1 of the first stiffness reinforcement structure 110 and the second thickness T2 of the second stiffness reinforcement structure 210.

Referring to FIG. 4, the warpage on the base wafer W may decrease, as the thickness of the semiconductor device carrier assembly CA increases.

For example, when the thickness of the carrier assembly is greater than 800 μm, warpage of the base wafer W may be reduced compared to the case that the thickness of the carrier assembly is 775 μm. Thus, when the thickness of the carrier assembly exceeds 800 μm, warpage of the base wafer W may be effectively prevented. Furthermore, because of increased thickness, alignment errors and process errors caused by warpage can be minimized.

For example, when the thickness of the carrier assembly exceeds 1160 μm, the warpage of the base wafer W may be less than 1200 μm, thereby effectively preventing warpage and reducing alignment and process errors.

As described above, the semiconductor device carrier assembly CA may include a first carrier 100 attached to the base wafer W and a second carrier 200 attached to the first carrier 100. The first carrier 100 may include the first stiffness reinforcement structure 110 and the first adhesive member 120 configured to attach the first stiffness reinforcement structure 110 to the base wafer W. The second carrier 200 may include the second stiffness reinforcement structure 210 and the second adhesive member 220 configured to attach the second stiffness reinforcement structure 210 to the first stiffness reinforcement structure 110.

The first and second stiffness reinforcement structures 110 and 210 may include at least one of silicon (Si) or glass to prevent warpage of the base wafer W.

Accordingly, the carrier assembly may reduce warpage of the wafer that occurs during the semiconductor manufacturing process. Furthermore, the carrier assembly can prevent alignment errors and process errors caused by warpage. Additionally, since pressing the wafer is not necessary to prevent warpage, the carrier assembly can prevent cracks from forming on the wafer.

Hereinafter, the method of manufacturing a semiconductor package using the carrier assembly CA in FIG. 1 will be described.

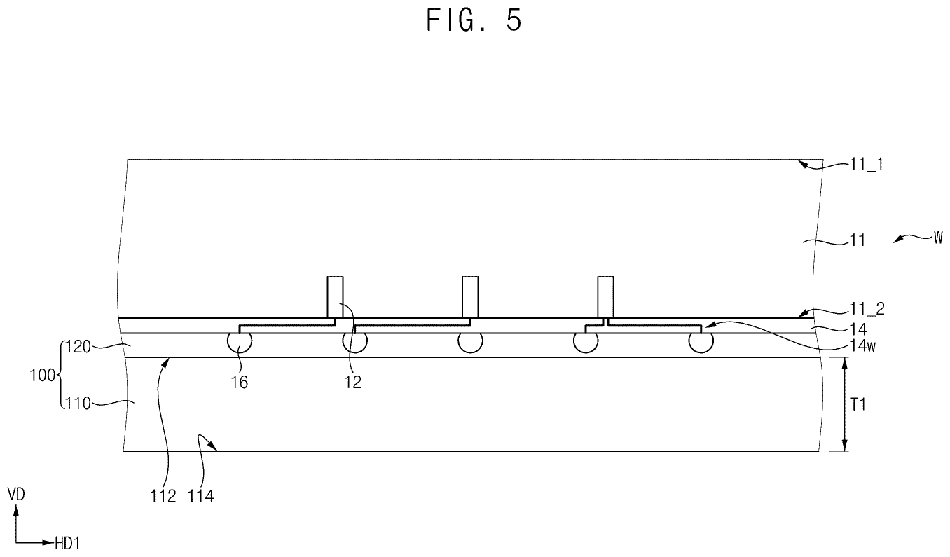

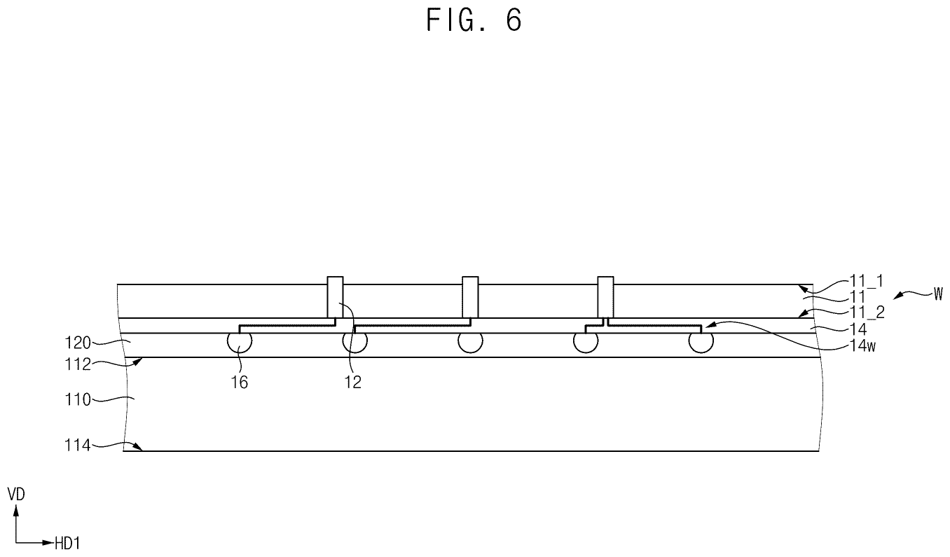

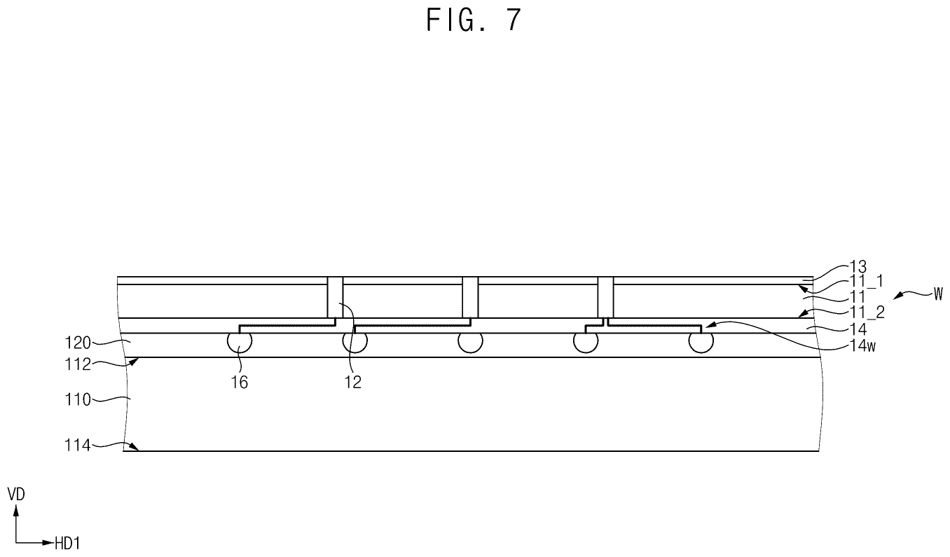

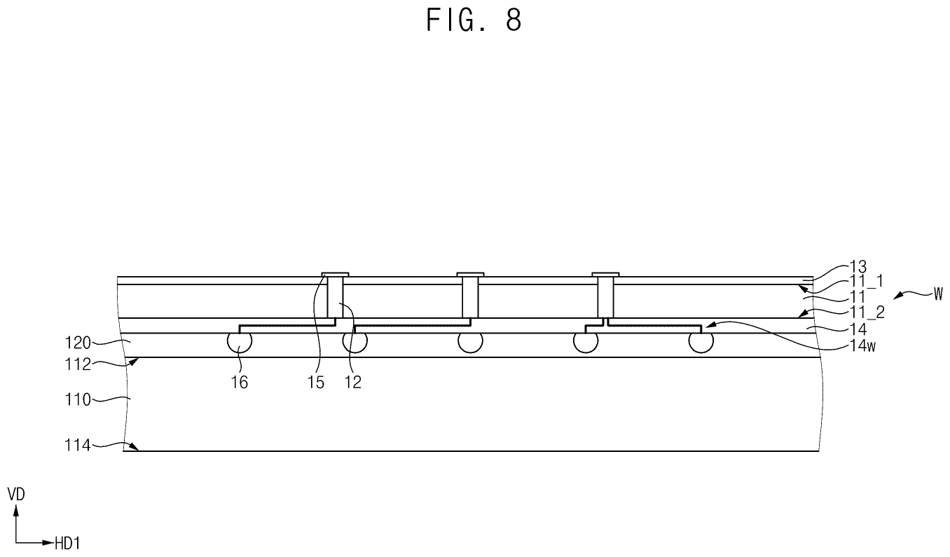

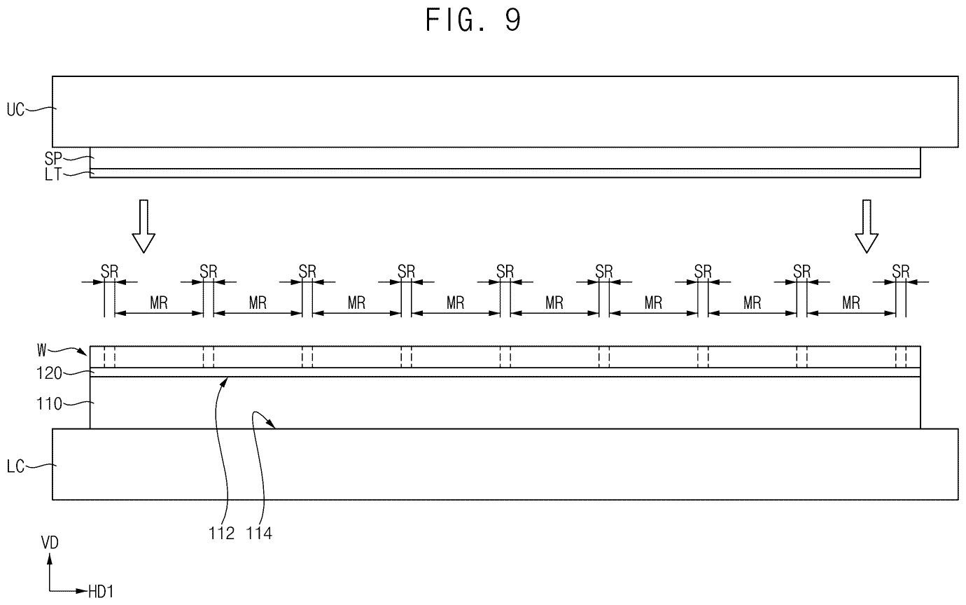

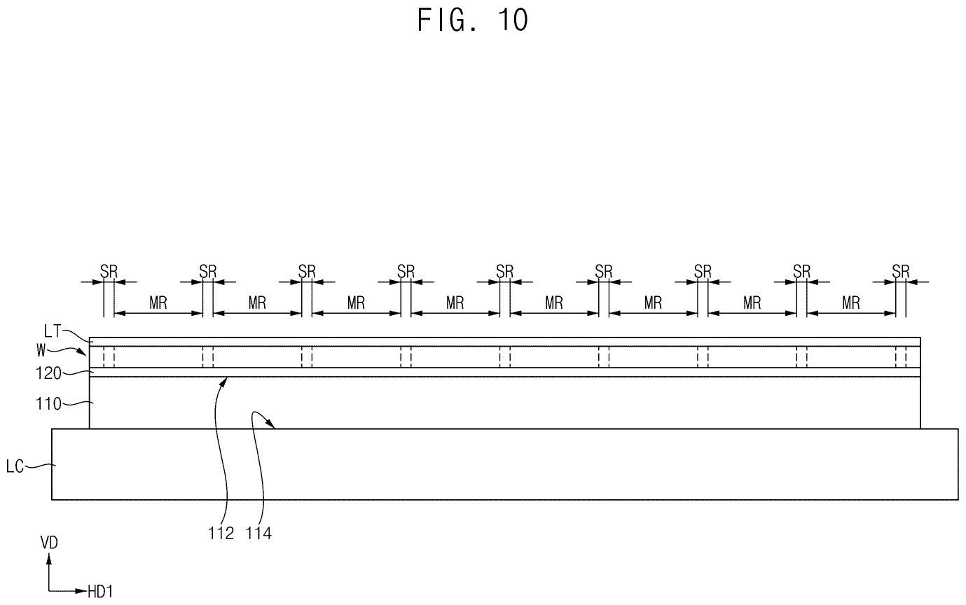

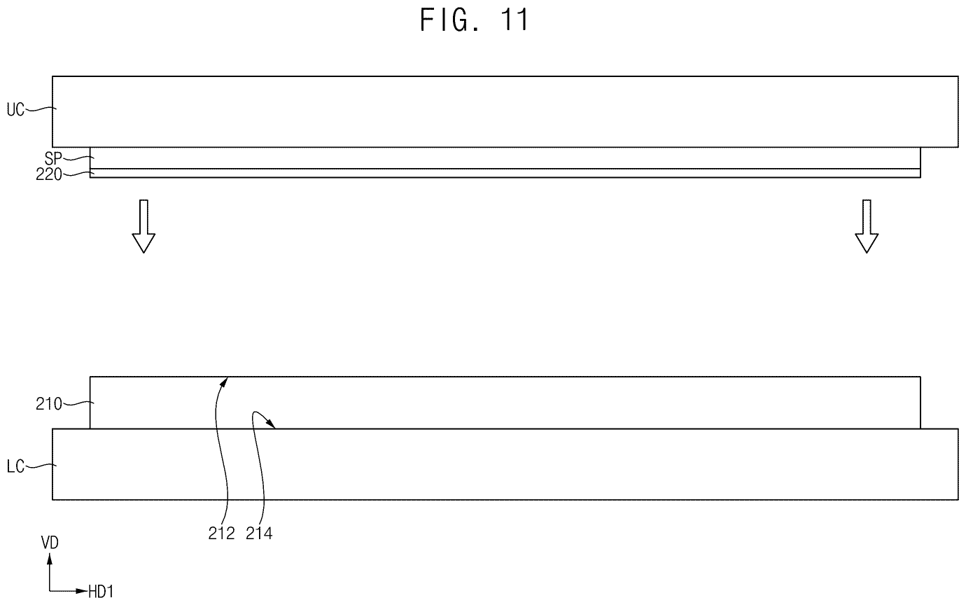

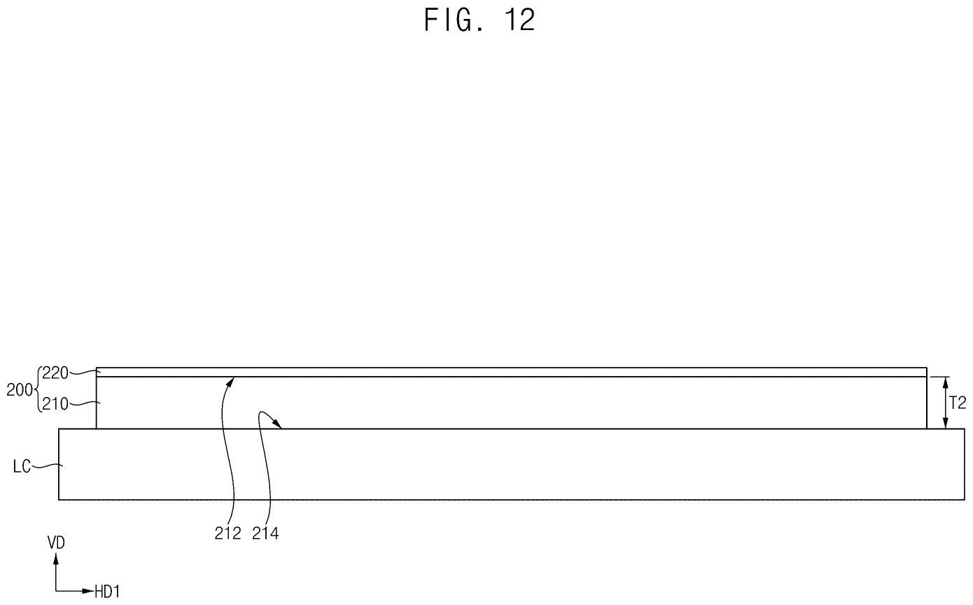

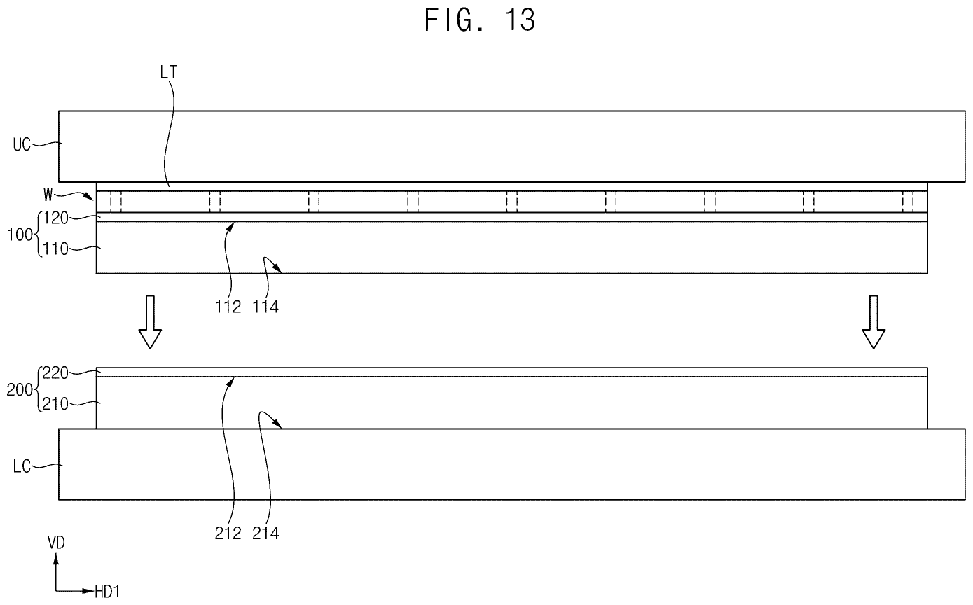

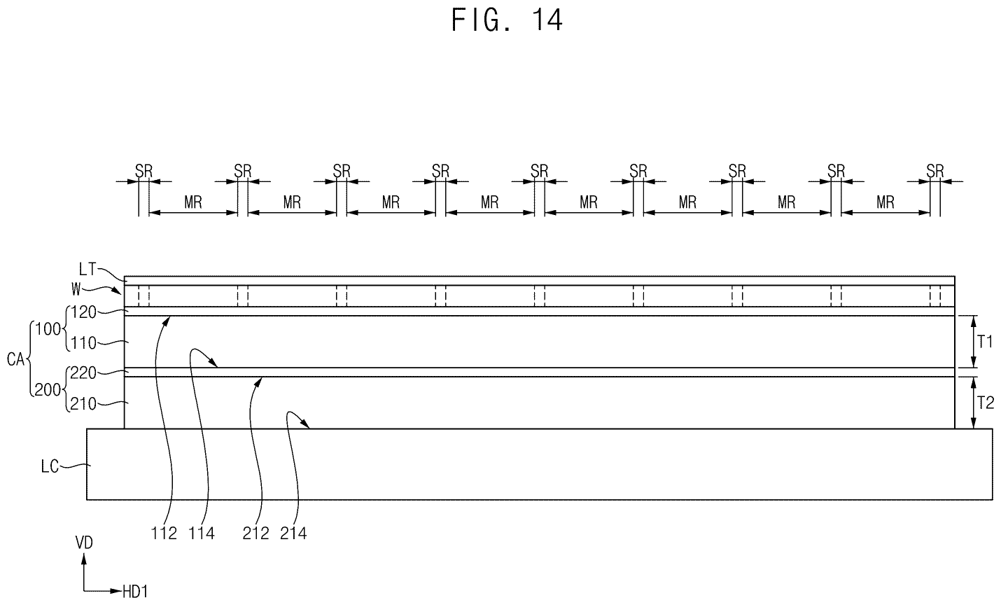

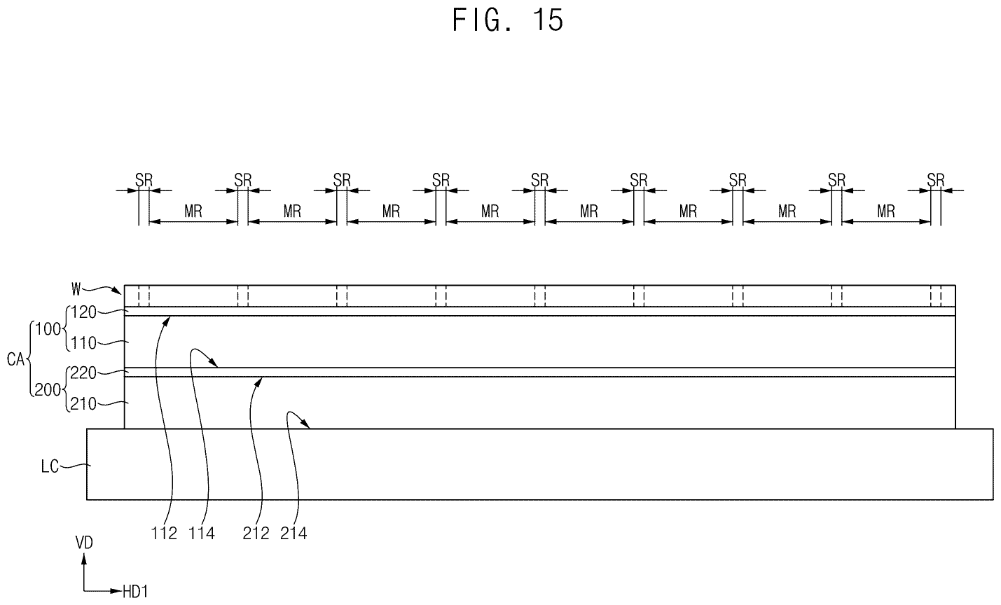

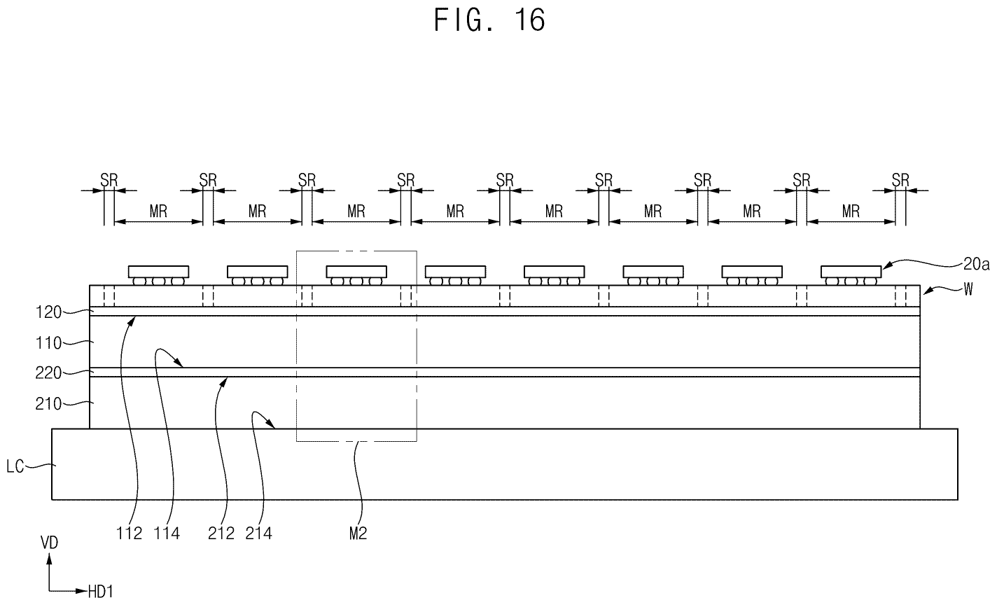

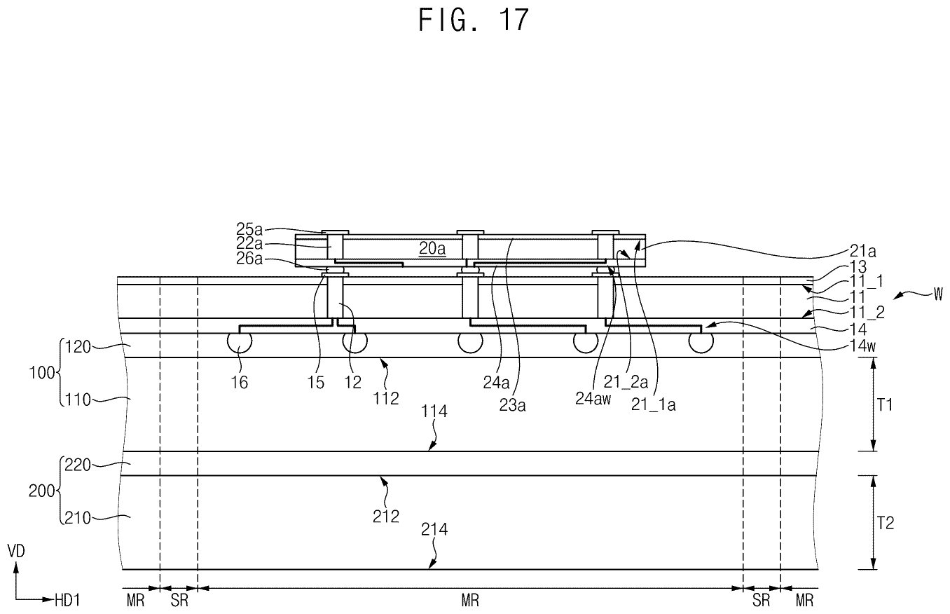

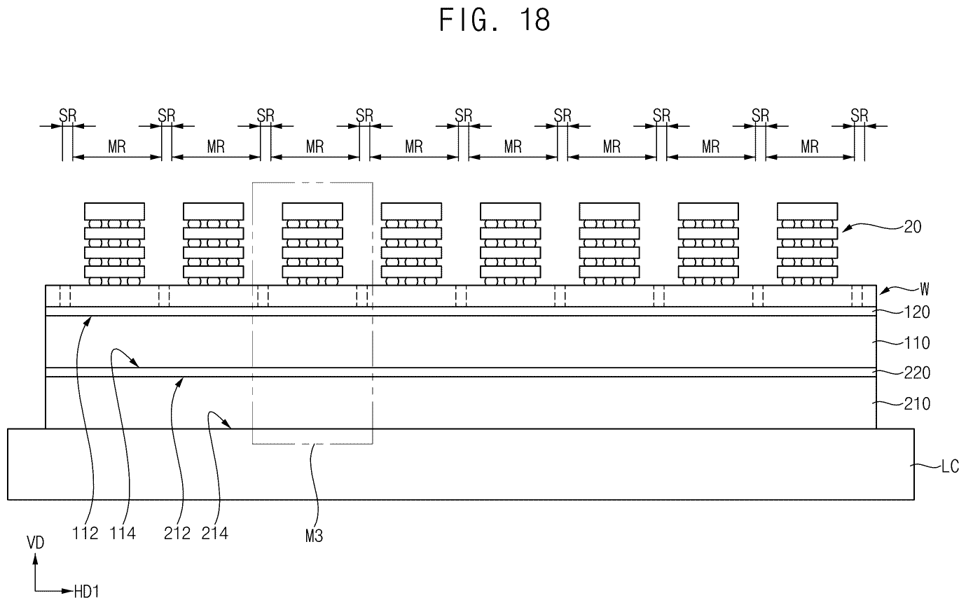

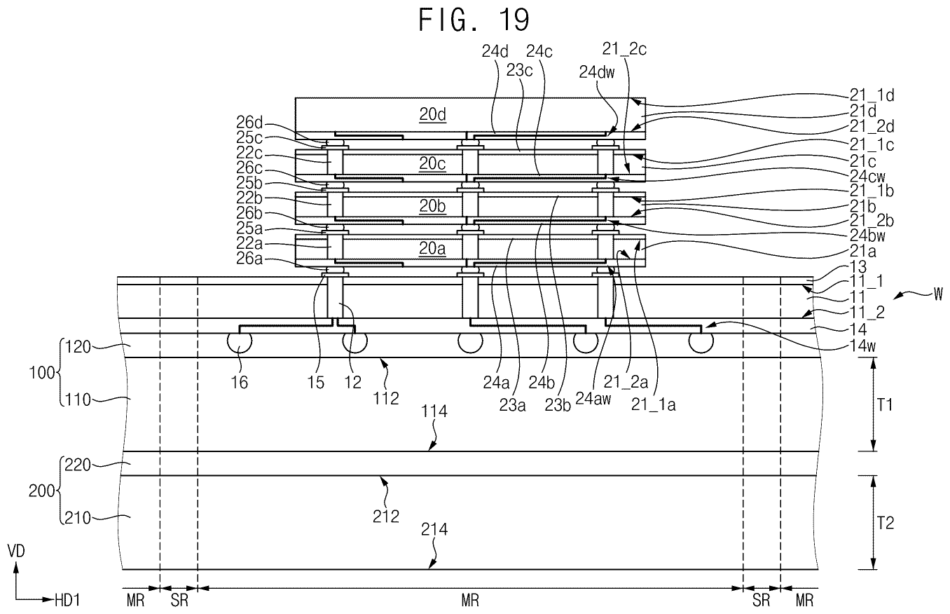

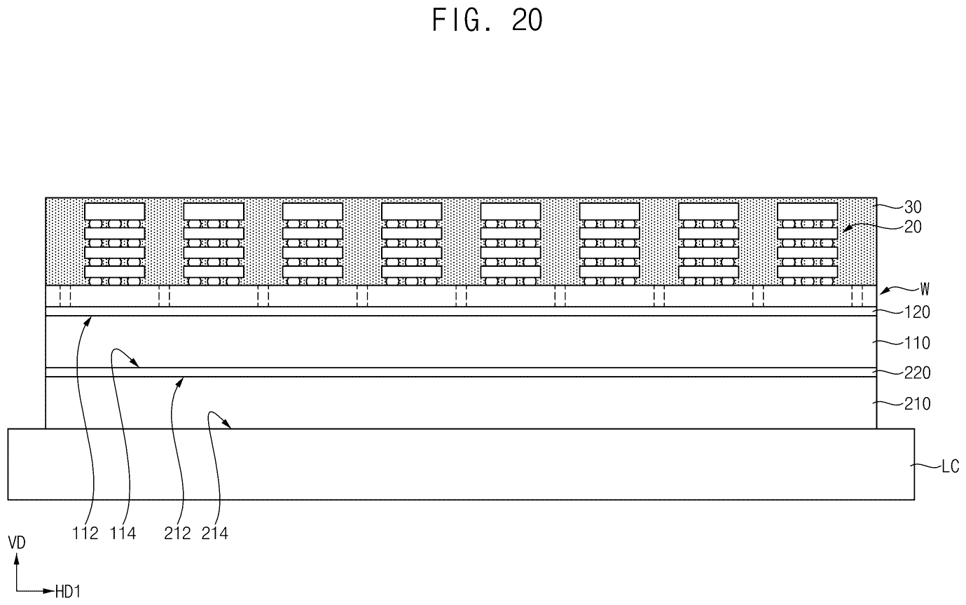

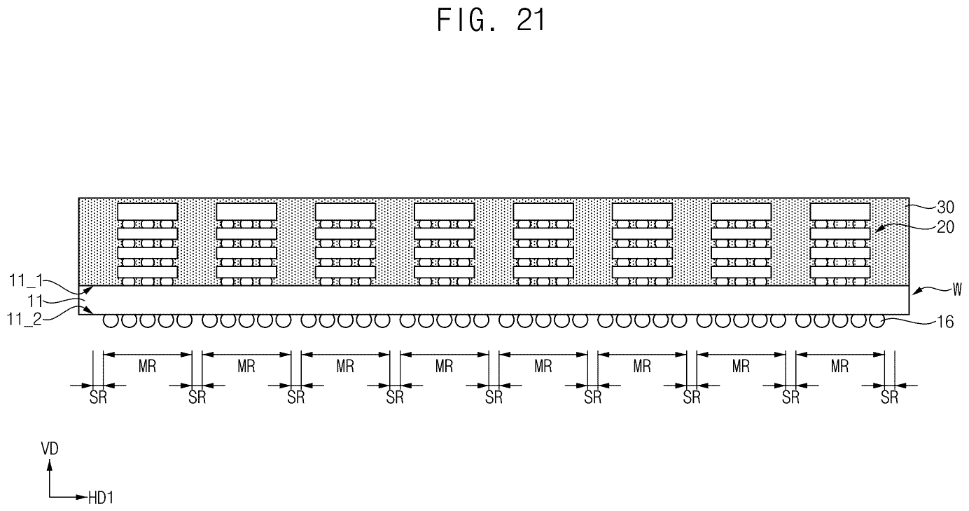

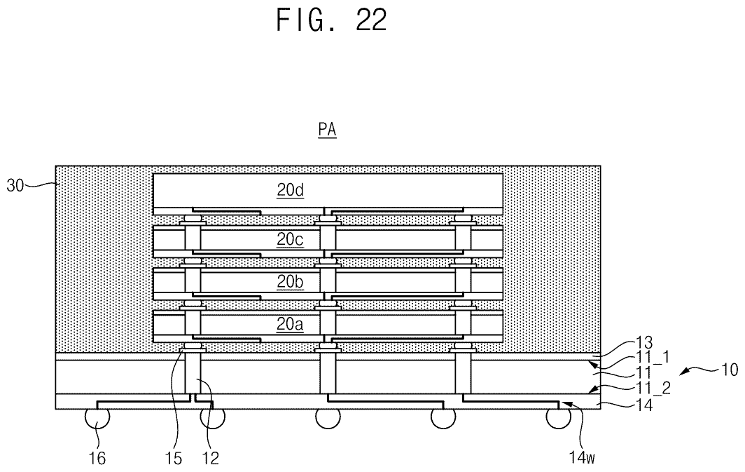

FIG. 5 is a cross-sectional view illustrating the base wafer disposed on the first carrier. FIG. 6 is a cross-sectional view illustrating the base wafer being polished to at least partially remove the base wafer. FIG. 7 is a cross-sectional view illustrating an insulation layer formed on the base wafer by performing a deposition process. FIG. 8 is a cross-sectional view illustrating upper pads formed on the base wafer. FIGS. 9 to 14 are views illustrating combining the first and second carriers to form the carrier assembly for semiconductor device. FIG. 15 is a cross-sectional view illustrating a lamination tape removed from the base wafer in FIG. 14. FIGS. 16 to 19 are views illustrating a plurality of semiconductor chips mounted on the base wafer in FIG. 15. FIG. 17 is an enlarged cross-sectional view illustrating portion ‘M2’ in FIG. 16. FIG. 19 is an enlarged cross-sectional view illustrating the portion ‘M3’ in FIG. 18. FIG. 20 is a cross-sectional view illustrating a molding member formed to cover the plurality of semiconductor chips. FIG. 21 is a cross-sectional view illustrating the carrier assembly separated from the base wafer. FIG. 22 is a cross-sectional view illustrating individual semiconductor packages by the singulation process.

The carrier assembly CA illustrated in FIGS. 5 to 22 is substantially the same as the carrier assembly CA described in FIGS. 1 to 4, so the same reference numerals are used for the same components and repetitive descriptions of the same components are omitted.

Referring to FIGS. 5 to 8, the base wafer W may be attached to the first carrier 100, the base wafer W may be polished, and the plurality of upper pads 15 may be formed on the base wafer W.

For example, the first carrier 100 including the first stiffness reinforcement structure 110 and the first adhesive member 120 may be provided.

In an example embodiment, the first carrier 100 may include the first stiffness reinforcement structure 110 attached to the front surface of the base wafer W and the first adhesive member 120 disposed between the first stiffness reinforcement structure 110 and the base wafer W.

The first stiffness reinforcement structure 110 may by configured to prevent warpage of the base wafer W during the manufacturing process of the semiconductor package. The first stiffness reinforcement structure 110 may include at least one of silicon (Si) or glass to prevent warpage of the base wafer W.

The first adhesive member 120 may serve to attach the first stiffness reinforcement structure 110 to the base wafer W. The first adhesive member 120 may include a high heat-resistant material to withstand the heat generated during the soldering process for electrically connecting the base wafer W and at least one semiconductor chip mounted on the backside surface of the base wafer W. For example, the first adhesive member may include epoxy material.

For example, the first adhesive member 120 may be attached to the second surface as the front surface 11_2 of the base wafer W such that the first adhesive member 120 formed on the second surface 11_2 of the base wafer W to cover the external connection members 16.

The first carrier 100 may be attached on the base wafer W via the first adhesive member 120 such that the second surface 11_2 of the base wafer W faces the first carrier 100.

After that, a polishing process may be performed from the first surface 11_1 of the base wafer W to partially remove the base wafer W such that the end portion of each of the through vias 12 of the base wafer W is at least partially exposed.

An upper insulation layer 13 W can be formed to cover the first surface 11_1 of the base wafer W by performing a deposition process on the first surface 11_1 of the base wafer W. Then, the upper insulation layer 13 may be at least partially removed to expose the end portion of each of the through vias 12 of the base wafer W by performing an etching process. And, a photolithography process may be performed on the exposed end portion of each of the through vias 12 to form a plurality of upper pads 15.

Referring to FIGS. 9 to 14, a lamination tape LT may be attached to the base wafer W which is secured to the first carrier 100, and the first carrier 100 may be attached to the second carrier 200, thereby forming a carrier assembly for a semiconductor device CA for handling the base wafer W and preventing warpage of the base wafer W.

For example, the lamination tape LT fixed to a support portion SP of an upper chuck UC may be moved to the base wafer W secured to the first carrier 100 fixed on a lower chuck LC. By using the adhesion strength of the lamination tape LT and the pressure applied by the support portion SP of the upper chuck UC, the lamination tape LT may be attached to the first surface 11_1 of the base wafer W, which is the backside surface of the wafer. The lamination tape LT may be disposed on the first surface 11_1 of the base wafer W to cover a plurality of upper pads 15 for physically protecting the plurality of upper pads 15.

Then, the second adhesive member 220 fixed to the support portion SP of the upper chuck UC may be moved to the second carrier 200 fixed on the lower chuck LC, and the second adhesive member 220 may be attached to the second stiffness reinforcement structure 210, thereby manufacturing the second carrier 200 which includes the second stiffness reinforcement structure 210 and the second adhesive member 220.

In example embodiments, the second carrier 200 may include the second stiffness reinforcement structure 210 attached to the first carrier 100 and the second adhesive member 220 disposed between the first stiffness reinforcement structure 110 and the second stiffness reinforcement structure 210.

The second stiffness reinforcement structure 210 may be configured to prevent warpage of the base wafer W during the manufacturing process of the semiconductor package. The second stiffness reinforcement structure 210 may include at least one of silicon Si or glass to prevent warpage of the base wafer W. For example, the second stiffness reinforcement structure 210 may be a silicon wafer used in semiconductor manufacturing processes.

The second adhesive member 220 may be a structure to attach the first stiffness reinforcement structure 110 and the second stiffness reinforcement structure 210. The second adhesive member 220 may include a high heat-resistant material to withstand heat generated during the soldering process used to electrically connect at least one semiconductor chip, which is mounted on the backside surface of the base wafer W, and the base wafer W. For example, the second adhesive member may include an epoxy material.

After that, using the upper chuck UC, the first carrier 100 and the base wafer W may move together by fixing the base wafer W, which is attached to the first carrier 100, such that the lamination tape LT contacts the lower surface of the upper chuck UC. The first carrier 100 and the base wafer W fixed to the upper chuck UC may be moved onto the second carrier 200 fixed to the lower chuck LC, and the first carrier 100 and the second carrier 200 may be integrally connected, by manufacturing the carrier assembly CA.

In example embodiments, the semiconductor device carrier assembly CA may be configured to handle the wafer during the manufacturing process of semiconductor package. The carrier assembly may be configured to prevent warpage of the wafer during the semiconductor package manufacturing process by being attached to one surface of the wafer.

The carrier assembly CA may include the first stiffness reinforcement structure 110 and the second stiffness reinforcement structure 210. Therefore, the carrier assembly CA may have relatively high stiffness, thereby effectively preventing warpage of the base wafer W.

The first adhesive member 120 may have a first adhesion strength, and the second adhesive member 220 may have a second adhesion strength greater than or equal to the first adhesion strength. For example, the first adhesive member may detachably attach the first stiffness reinforcement structure 110 and the base wafer W, while the second adhesive member may integrally attach the first stiffness reinforcement structure 110 and the second stiffness reinforcement structure 210. For example, the second adhesive member may attach the first stiffness reinforcement structure 110 and the second stiffness reinforcement structure 210 in a way that allows the first stiffness reinforcement structure 110 and the second stiffness reinforcement structure 210 to be separated or permanently attached.

Referring to FIG. 15, the lamination tape LT attached to the first surface 11_1 of the base wafer W may be removed to expose the plurality of upper pads 15 on the base wafer W.

Referring to FIGS. 16 to 19, a plurality of semiconductor chips 20 may be sequentially mounted on the first surface 11_1 of the base wafer W.

For example, a first semiconductor chip 20a may be mounted on each of a plurality of mounting regions of the base wafer W. By applying heat and pressure to the base wafer W, which is fixed to the carrier assembly CA, and the first semiconductor chip 20a, the first conductive connection member 26a disposed between the base wafer W and the first semiconductor chip 20a may be melted. After that, the first conductive connection member 26a may be cooled and solidified, thereby mechanically and electrically connecting the base wafer W and the first semiconductor chip 20a.

And, the second semiconductor chip 20b, third semiconductor chip 20c, and fourth semiconductor chip 20d may be sequentially mounted on the first semiconductor chip 20a by the same method of the first semiconductor chip.

Referring to FIG. 20, molding material may be injected onto the first surface 11_1 of the base wafer W, and the molding material may be cured to form a molding member 30 covering the plurality of semiconductor chips 20.

Referring to FIGS. 21 and 22, the base wafer W may be separated from the carrier assembly CA, and the base wafer W may be cut along the scribe lane area SR to complete the semiconductor package PA.

As described above, in the manufacturing method of a semiconductor package in accordance with example embodiments, the base wafer W may be fixed and handled via the carrier assembly CA, which includes a plurality of stiffness reinforcement structures 110 and 210.

As a result, during the manufacturing process of the semiconductor package, the carrier assembly CA can reduce the warpage of the base wafer W. Furthermore, the carrier assembly CA can reduce alignment errors and process errors caused by the warpage of the base wafer W.

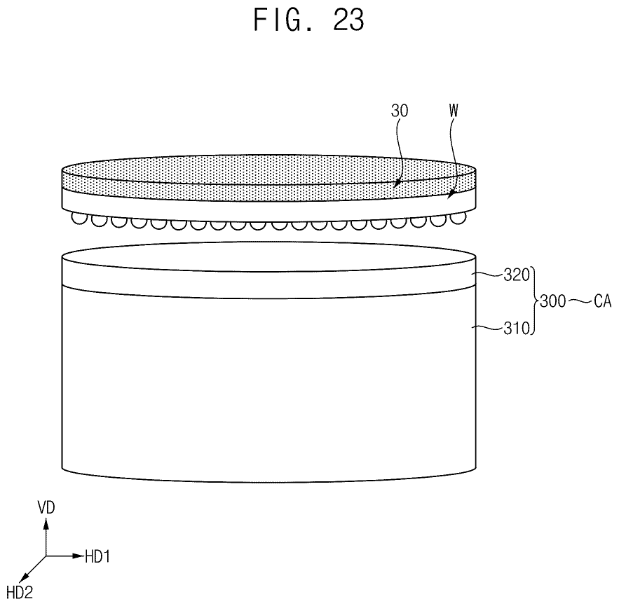

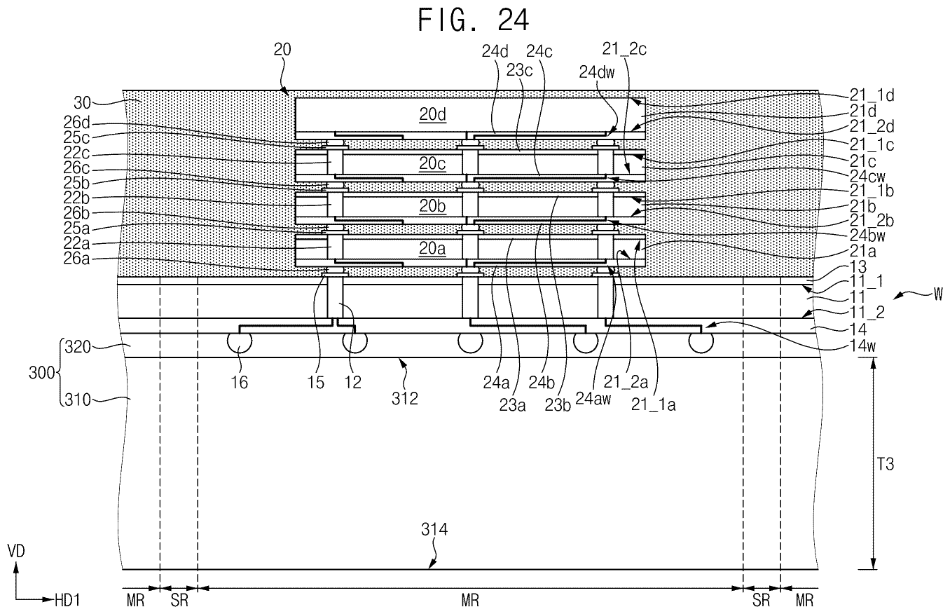

FIG. 23 is a perspective view illustrating a carrier assembly for semiconductor device according to example embodiments. FIG. 24 is an enlarged cross-sectional view illustrating the carrier assembly for semiconductor device of FIG. 23.

Referring to FIGS. 23 and 24, the carrier assembly CA may include a third carrier 300 having a third stiffness reinforcement structure 310 and a third adhesive member 320.

In example embodiments, the third carrier 300 may include the third stiffness reinforcement structure 310 attached to the front surface of the base wafer W and the third adhesive member 320 disposed between the third stiffness reinforcement structure 310 and the base wafer W. The third carrier may be directly contact with the base wafer W such that the third carrier is integrally combined with the base wafer to be configured to handle the base wafer W.

The third stiffness reinforcement structure 310 may include at least one of silicon (Si) or glass to prevent warpage of the base wafer W. For example, the third stiffness reinforcement structure may be a silicon wafer.

The third adhesive member 320 may be configured to bond the third stiffness reinforcement structure 310 and the base wafer W. For example, the third adhesive member may cover the front surface of the base wafer W to integrally combine the third stiffness reinforcement structure 310 with the base wafer W.

The third adhesive member 320 may include a high heat-resistant material to withstand heat generated during the soldering process for electrically connecting at least one semiconductor chip mounted on the backside surface of the base wafer W to the base wafer W. For example, the third adhesive member may include an epoxy material.

The third stiffness reinforcement structure 310 of the third carrier 300 may have a third thickness T3.

For example, the third thickness T3 may be greater than 775 μm. For example, in semiconductor manufacturing processes, a silicon wafer with a thickness of 775 μm may be used to handle the wafer. Accordingly, the carrier assembly CA may have a stiffness greater than the silicon wafer, effectively preventing the warpage of the base wafer W.

For example, in case that the thickness of carrier assembly CA may be greater than 780 μm, the warpage of the base wafer W can be reduced compared to the case that the thickness of carrier assembly CA is 775 μm. Thus, when the thickness of the carrier assembly CA is greater than 780 μm, the carrier assembly CA can effectively prevent warpage of the base wafer W. Additionally, alignment errors and process errors caused by warpage can be reduced.

As the thickness T3 of the third stiffness reinforcement structure increases, the semiconductor device carrier assembly CA may have a stronger stiffness, thereby effectively preventing warpage (bending) of the base wafer W.

For example, the third thickness T3 may be within the range of 780 μm to 1550 μm. When the third thickness T3 may be within the range of 780 μm to 1550 μm, the semiconductor device carrier assembly CA may have a relatively strong stiffness, thereby effectively preventing warpage of the base wafer W.

Referring again to FIG. 4, when the thickness of the semiconductor device carrier assembly CA is greater than 800 μm, the warpage of the base wafer W can be reduced compared to the case that the thickness is 775 μm. Therefore, when the thickness of the carrier assembly CA is greater than 800 μm, the assembly can effectively prevent warpage of the base wafer W. Moreover, alignment errors and process errors caused by warpage can be reduced.

For example, in case that the thickness of the stiffness reinforcement structure included in the carrier assembly CA is greater than 1160 μm, warpage of the base wafer W is effectively reduced. For example, even if the number of semiconductor chips mounted on the base wafer W increases, the warpage of the base wafer W can be smaller than 1200 μm.

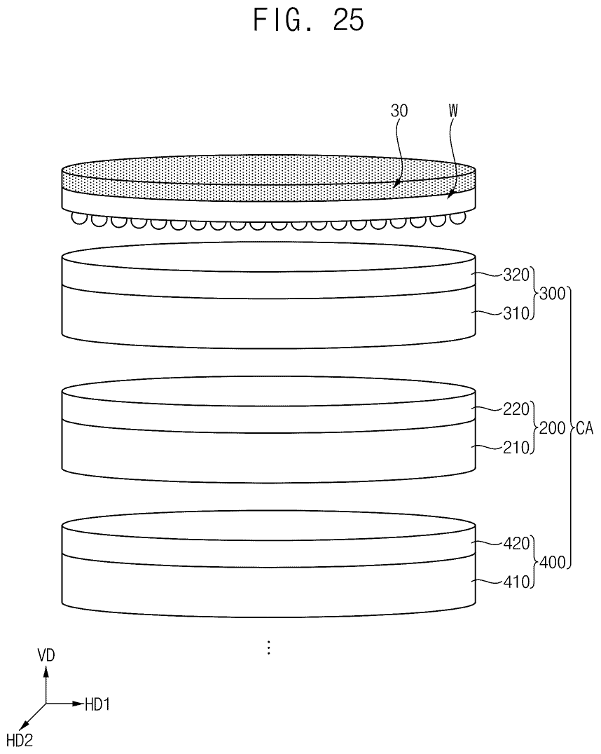

FIG. 25 is a perspective view illustrating a carrier assembly for semiconductor device according to example embodiments.

As illustrated on FIG. 25, the carrier assembly CA may be substantially the same as the carrier assembly CA described in FIGS. 1 to 4, except for at least one fourth carrier. Therefore, the same components are represented by the same reference numerals, and repetitive explanations for these components are omitted.

Referring to FIG. 25, the carrier assembly CA may include a first carrier 100, a second carrier 200, and at least one fourth carrier 400. The carrier assembly may be directly contact with the base wafer W such that the carrier assembly is integrally coupled with the base wafer W to be configured to handle the base wafer W.

In example embodiments, the at least one fourth carrier 400 may include at least one fourth stiffness reinforcement structure 410 and at least one fourth adhesive member 420. Since the at least one fourth carrier is substantially identical to the first and second carriers, a detailed explanation is omitted.

Although the figures may illustrate that the at least one fourth carrier 400 includes a single carrier, it should be understood that the present inventive concept is not limited to this. Therefore, the number of fourth carriers 400 can be changed.

The carrier assembly CA may include three or more carriers. As the number of carriers in the s carrier assembly CA increases, the stiffness of the assembly increases, thereby effectively preventing warpage of the base wafer W. Additionally, alignment errors and process errors caused by warpage can be reduced.

The package may include semiconductor devices such as logic devices or memory devices. The package may include, for example, logic devices such as a central processing unit (CPU, MPU), application processors (AP), volatile memory devices such as SRAM and DRAM devices, and non-volatile memory devices such as flash memory devices, PRAM, MRAM, and RRAM devices.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A carrier assembly for a semiconductor device, comprising:
a first carrier attached to a front surface of a base wafer, the first carrier including:
a first stiffness reinforcement structure having a first surface facing the base wafer and a second surface opposite to the first surface; and
a first adhesive member disposed between the first surface of the first stiffness reinforcement structure and the front surface of the base wafer; and
a second carrier attached to the second surface of the first stiffness reinforcement structure, the second carrier including:
a second stiffness reinforcement structure having a first surface facing the base wafer and a second surface opposite to the first surface of the second stiffness reinforcement structure; and
a second adhesive member disposed between the first stiffness reinforcement structure and the second stiffness reinforcement structure.

2. The carrier assembly of claim 1, wherein an adhesion strength of the second adhesive member is greater than or equal to an adhesion strength of the first adhesive member.

3. The carrier assembly of claim 1, wherein the first adhesive member detachably connects the first stiffness reinforcement structure to the base wafer.

4. The carrier assembly of claim 1, wherein the second adhesive member integrally connects the first stiffness reinforcement structure to the second stiffness reinforcement structure.

5. The carrier assembly of claim 1, wherein the first adhesive member and the second adhesive member include a high heat-resistant material for withstanding heat generated during a soldering process of electrically connecting at least one semiconductor chip, which is to be mounted on a backside surface of the base wafer, to the base wafer.

6. The carrier assembly of claim 5, wherein the first adhesive member and the second adhesive member include an epoxy material.

7. The carrier assembly of claim 1, wherein each of the first stiffness reinforcement structure and the second stiffness reinforcement structure includes at least one of silicon (Si) or glass to prevent warpage of the base wafer.

8. The carrier assembly of claim 1, wherein the first stiffness reinforcement structure has a first thickness, and the second stiffness reinforcement structure has a second thickness, and
wherein a sum of the first thickness and the second thickness is within a range from 780 μm to 1550 μm.

9. The carrier assembly of claim 8, wherein the first thickness of the first stiffness reinforcement structure is substantially same as the second thickness of the second stiffness reinforcement structure.

10. The carrier assembly of claim 9, wherein each of the first thickness of the first stiffness reinforcement structure and the second thickness of the second stiffness reinforcement structure is about 775 μm.

11. A carrier assembly for a semiconductor device, comprising:
a plurality of stiffness reinforcement structures each including at least one of silicon (Si) or glass to prevent warpage of a base wafer;
a first adhesive member having a first adhesion strength, the first adhesive member disposed between a front surface of the base wafer and an uppermost stiffness reinforcement structure among the plurality of stiffness reinforcement structures such that the uppermost stiffness reinforcement structure is detachably connected to the base wafer; and
at least one second adhesive member having a second adhesion strength greater than the first adhesion strength, the at least one second adhesive member disposed between the plurality of stiffness reinforcement structures to integrally connect the plurality of stiffness reinforcement structures to one another.

12. The carrier assembly of claim 11, wherein the first adhesive member and the at least one second adhesive member include a high heat-resistant material for withstanding heat generated during a soldering process of electrically connecting at least one semiconductor chip, which is to be mounted on a backside surface of the base wafer, to the base wafer.

13. The carrier assembly of claim 12, wherein the first adhesive member and the at least one second adhesive member include an epoxy material.

14. The carrier assembly of claim 11, wherein the plurality of stiffness reinforcement structures include a first stiffness reinforcement structure as the uppermost stiffness reinforcement structure attached to the base wafer via the first adhesive member and a second stiffness reinforcement structure attached to the first stiffness reinforcement structure via the at least one second adhesive member.

15. The carrier assembly of claim 14, wherein the first stiffness reinforcement structure has a first thickness, and the second stiffness reinforcement structure has a second thickness, and
wherein a sum of the first thickness and the second thickness is within a range from 780 μm to 1550 μm.

16. The carrier assembly of claim 15, wherein the first thickness of the first stiffness reinforcement structure is substantially same as the second thickness of the second stiffness reinforcement structure.

17. The carrier assembly of claim 16, wherein each of the first thickness of the first stiffness reinforcement structure and the second thickness of the second stiffness reinforcement structure is about 775 μm.

18. The carrier assembly of claim 11, wherein the base wafer includes a plurality of external connection members on the front surface of the base wafer, and
wherein the first adhesive member is attached to the front surface of the base wafer to cover the plurality of external connection members for physically protecting the plurality of external connection members.

19. A carrier assembly for semiconductor device, comprising:
a first stiffness reinforcement structure including at least one of silicon (Si) or glass to prevent warpage of a base wafer, the first stiffness reinforcement structure having a first thickness;
a first adhesive member having a first adhesion strength, the first adhesive member disposed between the first stiffness reinforcement structure and the base wafer such that the first stiffness reinforcement structure is detachably attached to the base wafer;
a second stiffness reinforcement structure spaced apart in a vertical direction from the first stiffness reinforcement structure, the second stiffness reinforcement structure including at least one of silicon (Si) or glass to prevent warpage of the base wafer, the second stiffness reinforcement structure having a second thickness; and
a second adhesive member having a second adhesion strength greater than the first adhesion strength, the second adhesive member disposed between the first stiffness reinforcement structure and the second stiffness reinforcement structure such that the first and second stiffness reinforcement structures are integrally connected to each other,
wherein a sum of the first thickness and the second thickness is within a range from 780 μm to 1550 μm.

20. The carrier assembly of claim 19, wherein the first thickness of the first stiffness reinforcement structure is substantially same as the second thickness of the second stiffness reinforcement structure.
